(19) United States
(12) Patent Application Publication
(10) Pub. No.: US 2015/0004363 A1
(43) Pub. Date: Jan. 1, 2015

(54) COATED ARTICLE AND METHOD FOR MAKING SAME

(71) Applicants: FIH (Hong Kong) Limited, Kowloon (HK); SHENZHEN FUTAIHONG PRECISION INDUSTRY CO., LTD., Shenzhen (CN)

(72) Inventor: CHUN-JIE ZHANG, Shenzhen (CN)

(21) Appl. No.: 13/935,902

(22) Filed: Jul. 5, 2013

(30) Foreign Application Priority Data
Jun. 27, 2013 (CN) 2013102702324

(51) Int. Cl. B08B 17/06; C23C 14/06; C23C 14/34

(52) U.S. Cl. CPC B08B 17/065; C23C 14/3414; C23C 14/0611
USPC 428/141; 204/192.15

(57) ABSTRACT

A coated article includes a substrate and a diamond-like carbon layer formed on the substrate. The diamond-like carbon layer has a plurality of nano-sized bumps on its outer surface. The nano-sized bumps alter the contact angle between a given fluid and the coated article, thus making the coated article extremely hydrophobic. The diamond-like carbon layer also makes the coated article extremely hard. A method for making the coated article is also provided.

### BACKGROUND

1. Technical Field

The present disclosure relates to a coated article, particularly to a coated article being extremely hydrophobic and a method for making the coated article.

2. Description of Related Art

A coated article having a high hardness and excellent hydrophobic property may be manufactured by the two following methods: one method is depositing a silicon (Si) doped diamond-like carbon (DLC) layer on a glass/ceramic substrate; another method is forming a layer containing fluoroalkylsilane (FAS) on a glass/ceramic substrate coated with a DLC layer. However, the DLC layer cannot be securely bonded to the glass/ceramic substrate and is prone to peeling, which will adversely affect the hardness and hydrophobic property.

Therefore, there is room for improvement within the art.

### BRIEF DESCRIPTION OF THE FIGURES

Many aspects of the coated article can be better understood with reference to the following figures. The components in the figures are not necessarily drawn to scale, the emphasis instead being placed upon clearly illustrating the principles of the coated article.

FIG. 1 is a cross-sectional view of an exemplary embodiment of a coated article.

FIG. 2 is a cross-sectional view of an exemplary embodiment of a vacuum evaporation coating machine.

FIG. 3 is a cross-sectional view of an exemplary embodiment of a vacuum sputtering coating machine.

### DETAILED DESCRIPTION

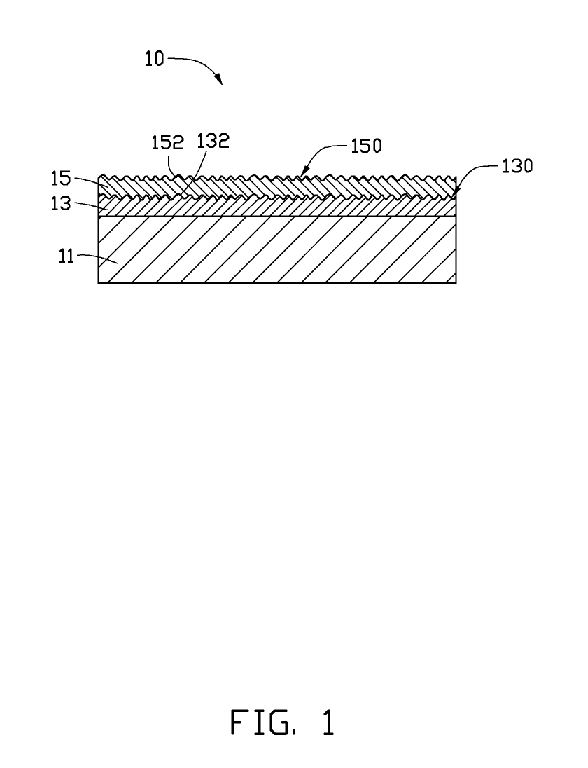

FIG. 1 shows an exemplary embodiment of a coated article 10, which includes a substrate 11, a metal layer 13 formed on the substrate 11, and a diamond-like carbon (DLC) layer 15 formed on the metal layer 13.

The substrate 11 may be made of glass, stainless steel, high-speed steel, or die steel.

The metal layer 13 is a tungsten (W) layer. The metal layer 13 has a plurality of first nano-sized bumps 132 on a surface 130 bonding with the DLC layer 15. The metal layer 13 has a thickness between about 1 μm and about 2 μm.

The DLC layer 15 is directly formed on the surface 130 of the metal layer 13 and has a profile corresponding to a profile of the metal layer 13. The DLC layer 15 has a plurality of second nano-sized bumps 152 on an outer surface 150. The DLC layer consists of elemental carbon (C) and elemental hydrogen (H), wherein the mass percentage of the elemental carbon is between about 30% and about 40%, and the mass percentage of the elemental carbon is between about 60% and about 70%. The DLC layer 15 has a thickness between about 1 μm and about 1.5 μm.

A method for manufacturing the article 10 is also provided. The method may include the following steps:

(1) The substrate 11 is provided.

(2) The substrate 11 is pretreated.

The substrate 11 is washed with a solution (e.g., alcohol or acetone) in an ultrasonic cleaner to remove contaminations, such as grease or dirt. The substrate 11 is then dried.

(3) The metal layer 13 is deposited onto the substrate 11.

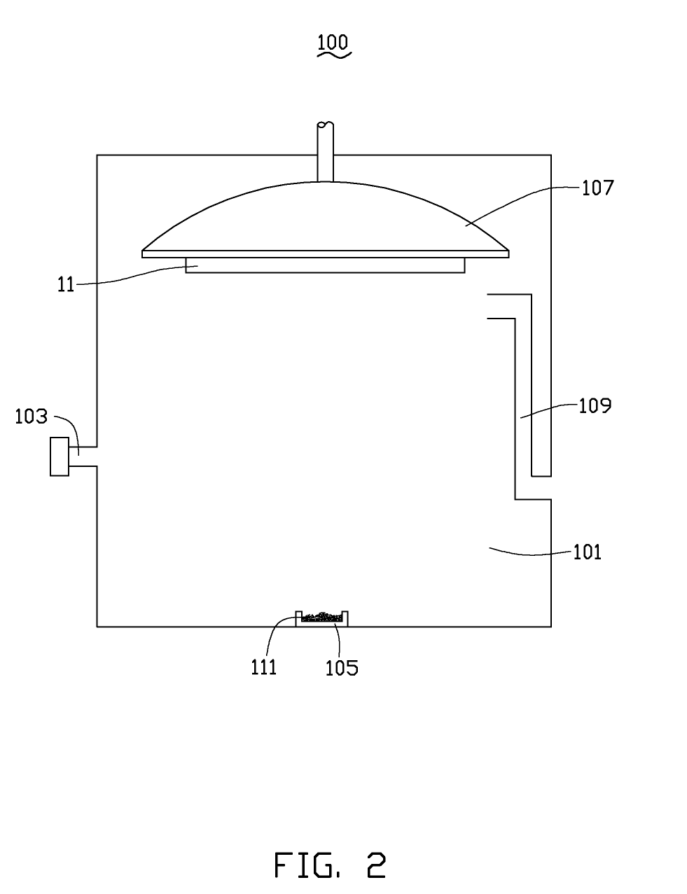

Referring to FIG. 2, a vacuum evaporation coating machine 100 is provided. The vacuum evaporation coating machine 100 includes an evaporation coating chamber 101 and a first vacuum pump 103 communicates with the evaporation coating chamber 101. The first vacuum pump 103 evacuates the evaporation coating chamber 101. The evaporation coating chamber 101 further includes an evaporation element 105, a positioning bracket 107, and a first gas inlet 109. The evaporation element 105 holds and heats evaporation material 111. The evaporation material 111 is made of tungsten.

The metal layer 13 is deposited onto the substrate 11. The substrate 11 is retained on the positioning bracket 107. The evaporation coating chamber 101 is evacuated to a pressure between about 3×10⁻³ Pascals (Pa) and about 8.0×10⁻³ Pa. The temperature inside the evaporation coating chamber 101 is set between about 150 degrees Celsius (° C.) and about 200° C. The deposit rate is between about 4 kiloangstroms per second (k Å/S) and about 4.5 k Å/S. The electric current is set between about 60 milliamperes (mA) and about 90 mA. Depositing the metal layer 13 takes about 40 minutes (min) to about 60 min.

(4) The metal layer 13 is cooled by liquid nitrogen.

After deposition of the metal layer 13, liquid nitrogen is fed into the evaporation coating chamber 101 to adjust the pressure in the evaporation coating chamber 101 between about 10⁻¹ Pa and about 1 Pa and the temperature inside the evaporation coating chamber 101 between about 80° C. and about 100° C. The substrate 11 coated with the metal layer 13 is retained in the evaporation coating chamber 101 with the liquid nitrogen atmosphere for about 2 min to about 3 min.

During the cooling treatment, crystalline grains on the surface 130 of the metal layer 13 are enlarged, thus forming the plurality of first nano-sized bumps 132. Liquid nitrogen prevents the metal layer 13 from oxidation, thus accelerating the formation of a hydrophobic surface on the metal layer 13.

(5) The DLC layer 15 is deposited onto the suddenly cooled metal layer 13.

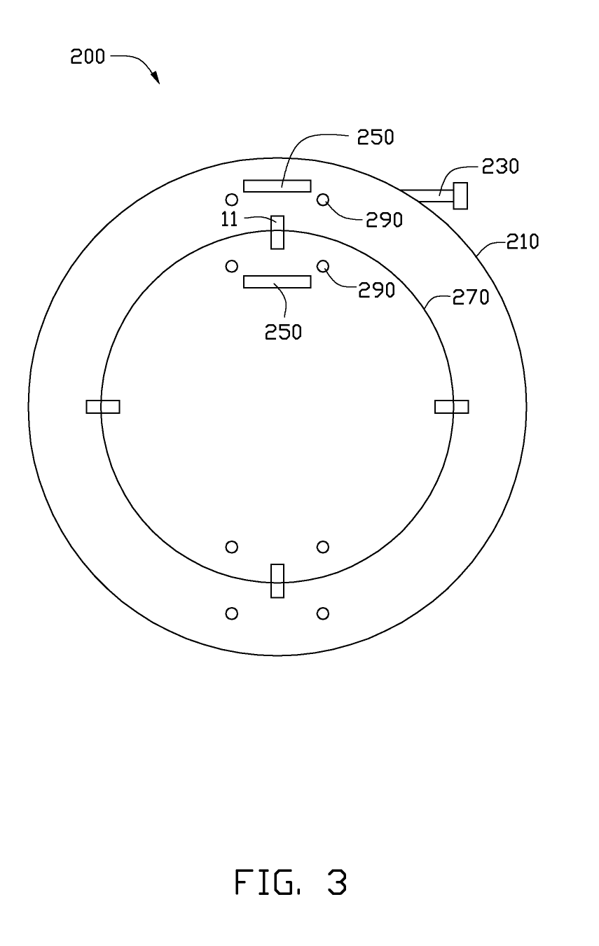

Referring to FIG. 3, the vacuum sputtering coating machine 200 includes a sputtering coating chamber 210 and a second vacuum pump 230 communicates with the sputtering coating chamber 210. The second vacuum pump 230 evacuates the sputtering coating chamber 210. The vacuum sputtering coating machine 200 further includes two graphite targets 250, a rotating bracket 270, and a plurality of second gas inlets 290. The rotating bracket 270 rotates the substrate 11 in the sputtering coating chamber 210 relative to the two graphite targets 250. The two graphite targets 250 face each other and are located on opposite sides of the rotating bracket 270.

The sputtering coating chamber 210 is evacuated to a pressure between about 0.1 Pa and about 0.3 Pa. The temperature inside the sputtering coating chamber 210 is set between about 230° C. and about 250° C. Argon gas is fed into the sputtering coating chamber 210 at a flux rate between about 150 Standard Cubic Centimeters per Minute (sccm) and about 200 sccm from the second gas inlets 290. Carbon-containing gas (e.g., methane, acetylene, ethanol, or acetone) is fed into the sputtering coating chamber 210 at a flux rate between about 100 sccm and about 150 sccm. The graphite targets 250 mounted in the sputtering coating chamber 210 are evaporated at an electric power between about 8 (kW) and about 10 kW. A bias voltage applied to the substrate 11 is between about −200 volts (V) and about −400 V. Depositing the DLC layer 15 takes about 40 min to about 60 min.

The DLC layer 15 has a profile corresponding to the profile of the metal layer 13 and has a plurality of second nano-sized bumps 152 formed thereon. The second nano-sized bumps 152 alter the contact angle between a given fluid and the coated article 10. Accordingly, the coated article 10 becomes extremely hydrophobic. The DLC layer 15 also makes the coated article 10 extremely hard.

The metal layer 13 cooled by liquid nitrogen enhances the bond between the substrate 11 and the DLC layer 15 to prevent the DLC layer 15 from peeling.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A coated article, comprising:
a substrate; and
a diamond-like carbon layer formed on the substrate, the diamond-like carbon layer comprising a plurality of nano-sized bumps on an outer surface thereof.

2. The coated article as claimed in claim 1, wherein the diamond-like carbon layer has a thickness between about 1 μm and about 1.5 μm.

3. The coated article as claimed in claim 1, wherein the diamond-like carbon layer consists of elemental carbon and elemental hydrogen.

4. The coated article as claimed in claim 3, wherein in the diamond-like carbon layer, the mass percentage of the elemental carbon is between about 30 and about 40%, the mass percentage of the elemental carbon is between about 60 and about 70%.

5. The coated article as claimed in claim 1, further comprising a metal layer formed between the substrate and the diamond-like carbon layer.

6. The coated article as claimed in claim 5, wherein the metal layer is tungsten layer.

7. The coated article as claimed in claim 5, wherein the metal layer comprises a plurality of nano-sized bumps on a surface thereof, the diamond-like carbon layer having a profile corresponding to a profile of the metal layer.

8. The coated article as claimed in claim 5, wherein the metal layer has a thickness of about 1 μm to about 2 μm.

9. The coated article as claimed in claim 1, wherein the substrate is made of glass, stainless steel, high speed steel or die steel.

10. A method for making a coated article, comprising:
providing a substrate;
forming a metal layer on the substrate;
cooling the metal substrate, crystal grains at the outer surface of the metal layer being enlarged and forming a plurality of nano-sized bumps on the outer surface of the metal layer;
vacuum depositing a diamond-like carbon layer on the cooled metal layer, the diamond-like carbon layer having a profile corresponding to a profile of the metal layer comprising a plurality of nano-sized bumps on its outer surface.

11. The method as claimed in claim 10, wherein the metal layer is a tungsten layer.

12. The method as claimed in claim 10, wherein the metal layer is formed by vacuum evaporation, uses a tungsten evaporation material with a deposit rate between about 4 k Å/S and about 4.5 k Å/S, and is carried out at a temperature of between about 150° C. and about 200° C. and a electric current of between about 60 mA and about 90 mA.

13. The method as claimed in claim 10, wherein the metal layer is cooled by liquid nitrogen.

14. The method as claimed in claim 10, wherein the metal layer is cooled by liquid nitrogen at a vacuum level of between about 10⁻¹ Pa and about 1 Pa and a temperature of about 80° C. and about 100° C. for about 2 min to about 3 min.

15. The method as claimed in claim 10, wherein during forming the diamond-like carbon layer, uses a graphite targets applied with a electric power of between about 8 kW and about 10 kW, uses carbon-containing gas at a flow rate of between about 30 sccm and about 100 sccm as a reaction gas; uses argon at a flow rate of between about 150 sccm and about about 200 sccm as a sputtering gas; applies a bias voltage of between about −200 V and about −400 V to the substrate; and is carried out at a temperature of between about 230° C. and about 250° C.
